(19) United States
(12) Patent Application Publication
(10) Pub. No.: US 2017/0062191 A1
(43) Pub. Date: Mar. 2, 2017

(54) Plasma-enhanced atomic layer deposition system with rotary reactor tube

(71) Applicant: Ultratech, Inc., San Jose, CA (US)

(72) Inventors: Arthur W. Zafiropoulo, Atherton, CA (US); Andrew M. Hawryluk, Los Altos, CA (US)

(73) Assignee: Ultratech, Inc., San Jose, CA (US)

(21) Appl. No.: 15/244,097

(22) Filed: Aug. 23, 2016

Related U.S. Application Data
(60) Provisional application No. 62/212,021, filed on Aug. 31, 2015.

(51) Int. Cl. H01J 37/32; C23C 16/511; C23C 16/44; C23C 16/455; C23C 16/458

(52) U.S. Cl. CPC H01J 37/32733; C23C 16/45529; C23C 16/45544; C23C 16/458; C23C 16/4408; C23C 16/45536; C23C 16/511; H01J 37/32458; H01J 37/32853; H01J 37/32247; H01J 37/3266; H01J 37/32467; H01J 37/32825; H01J 2237/3321; H01J 2237/20214

(57) ABSTRACT

Systems and methods for coating particles using PE-ALD and a rotary reactor tube are disclosed. The reactor tube is part of a reactor tube assembly that can rotate and move axially so that it is operably disposed relative to a plasma-generating device. The plasma-generating device has an active state that generates a plasma from a precursor gas and an inactive state that passes the precursor gas without forming a plasma. The reactor tube resides in a chamber that has an open position for accessing the reactor tube and a closed position that supports a vacuum. An output end of the plasma-generating device resides immediately adjacent or within an input section of the reactor tube. This configuration avoids the need for an active portion of the plasma-generating device residing adjacent an outer surface of the reactor tube.

### CLAIM OF PRIORITY

The present application claims priority under 35 USC 119(e) from Provisional Patent Application Ser. No. 62/212,021, filed on Aug. 31, 2015, and which is incorporated by reference herein.

### FIELD

The present disclosure relates to atomic layer deposition (ALD), and in particular to a plasma-enhanced ALD (PE-ALD) system with a rotary reactor tube for use in performing PE-ALD on particles.

The entire disclosure of any publication or patent document mentioned herein is incorporated by reference, including: U.S. Pat. Nos. 6,613,383; 6,713,177; 6,913,827; 7,132,697; 8,133,531; 8,163,336; 8,202,575, and 8,637,156 and U.S. Pre-Grant Publications No. 2007/298250; 2011/0200822; 2012/0009343; 2013/0059073; and 2013/0193835, and the following technical publications:
1) Longrie et al., “A rotary reactor for thermal and plasma-enhanced atomic layer deposition on powders and small objects,” Surface & Coatings Technology 212 (2012), 183-191; and
2) McCormick et al., “Rotary reactor for atomic layer deposition on large quantities of nanoparticles,” J. Vac. Sci. Technol. A 25(1), January/February 2007, pp. 67-74.

### BACKGROUND

ALD is a method of depositing a thin film on an object in a very controlled manner. The deposition process is controlled by using two or more chemicals (“precursors”) in vapor form and reacting them sequentially and in a self-limiting manner on the surface of the object. The sequential process is repeated to build up the thin film layer by layer, wherein the layers are atomic scale in thickness.

PE-ALD utilizes a plasma to deliver at least one of the precursors. This is because certain reactions require the precursor to be ionized. Without such ionization, the precursor may not be sufficiently reactive to form the desired material.

ALD can be used to form thin layers on particles. The particles are often 0.01 to 100's of microns in diameter. Performing ALD on particles is more difficult than on a 2D surface of a substrate because the particle coating is three-dimensional and the coating needs to cover the entire surface of the particle. Also, the total area being coated is relatively large when a large number of particles need to be coated. Consequently, there is a continuing need for improved systems and methods for performing ALD on particles.

### SUMMARY

Systems and methods for coating particles using PE-ALD and a rotary reactor tube are disclosed. The rotary reactor tube is part of a reactor tube assembly that can rotate and move axially so that it is operably disposed relative to a plasma-generating device. The plasma-generating device has an active state that generates a plasma from a precursor gas and an inactive state that passes the precursor gas without forming a plasma. The reactor tube resides in a chamber that has an open position for accessing the reactor tube and a closed position that supports a vacuum. An output end of the plasma-generating device resides immediately adjacent or within an input section of the reactor tube. This configuration avoids the need for an active portion of the plasma-generating device residing adjacent the outer surface of the reactor tube.

An aspect of the disclosure is a system for performing plasma-enhance atomic layer deposition (PE-ALD) of particles using at least first and second precursor gases. The system includes a chamber having top and bottom sections that define a chamber interior. The chamber is configured such that the top and bottom sections have an open position that provides access to the chamber interior and a closed position wherein the chamber interior holds a vacuum. The system also includes a reactor tube assembly operably arranged relative to the chamber. The reactor tube assembly includes a reactor tube that resides within the chamber interior and having a central axis, an outer surface, an interior, an input section, a center section that contains the particles, and an output section that includes at least one aperture in the outer surface. The reactor tube assembly is configured to rotate the reactor tube about the central axis. The system also includes a gas supply system that includes at least first and second precursor gases. The system also includes a plasma-generating device arranged within the chamber interior and adjacent or at least partially within the input section of the reactor tube along the central axis of reactor tube. The plasma-generating device has active and inactive states of operation and is operably connected to the gas supply system and configured to receive at least one of the first and second precursor gases. When in the active state form therefrom at least one corresponding plasma that is outputted therefrom and into the interior of the reactor tube via the input section. The system also includes a vacuum system that forms the vacuum in the chamber interior in the closed position, thereby forming the vacuum in the interior of reactor tube that causes the plasma to flow through the interior of the reactor tube and react with the particles therein.

Another aspect of the disclosure is the system described above, wherein at least one of the plasma-generating device and the reactor tube is axially movable along the central axis so that the plasma-generating device can be operably positioned relative to the input section of the reactor tube.

Another aspect of the disclosure is the system described above, wherein the top and bottom sections are mechanically coupled by a hinge.

Another aspect of the disclosure is the system described above, wherein the reactor tube is made of quartz or a ceramic.

Another aspect of the disclosure is the system described above, wherein the plasma-generating device is operably supported by a translation device configured to translate the plasma-generating device at least along the central axis of the reactor tube.

Another aspect of the disclosure is the system described above, wherein the reactor tube assembly further includes: a drive motor that resides external to the chamber interior; a support plate that supports the reactor tube at the output section, and; a drive shaft that mechanically connects the support plate to the drive motor.

Another aspect of the disclosure is the system described above, wherein the drive motor is movable such that the reactor tube is translatable along the central axis.

Another aspect of the disclosure is the system described above, the system further includes at least one heating device operably arranged to provide heat to the particles contained in the reactor tube.

Another aspect of the disclosure is the system described above, wherein the plasma-generating device includes either a hallow-anode plasma source or a hollow-cathode plasma source.

Another aspect of the disclosure is the system described above, wherein the drive frequency for the plasma source is between 200 kHz and 15 MHz.

Another aspect of the disclosure is the system described above, wherein the plasma-generating device includes an electron-cyclotron resonance (ECR) plasma source.

Another aspect of the disclosure is the system described above, wherein the ECR plasma source has a drive frequency of 2.4 GHz.

Another aspect of the disclosure is the system described above, wherein the plasma-generating device has a substantially cylindrical shape with an axial length between about 50 and 100 mm and a diameter between about 20 mm to 50 mm.

Another aspect of the disclosure is the system described above, wherein the reactor tube has the input and output sections have a first diameter D1. The center section has a second diameter D2, and the following inequality is satisfied: (1.25)·D1≦D2≦(3)·D1.

An aspect of the disclosure is a reactor tube assembly for a plasma-enhanced atomic layer deposition (PE-ALD) system for coating particles. The reactor tube assembly includes a reactor tube having a central axis, proximal and distal open ends, a body made of a dielectric material and having an outer surface that defines an interior, an input section that includes the proximal open end, an output section that includes that distal open end, a center section between the input and output sections and sized to contain the particles, with at least one aperture formed in the outer surface at the output section. The reactor tube assembly also includes a support plate operably attached to the distal open end of the reactor tube. The reactor tube assembly also includes a drive motor and a drive shaft. The drive shaft mechanically connects the drive motor to the support plate so that the reactor tube rotates about its central axis when the drive motor rotatably drives the drive shaft.

Another aspect of the disclosure is the reactor tube assembly described above, wherein the input and output sections have a first diameter D1. The center section has a second diameter D2. The following inequality is completed. (1.25)·D1≦D2≦(3)·D1.

Another aspect of the disclosure is the reactor tube assembly described above, wherein the reactor tube assembly further includes inwardly extending vanes in the center section of the reactor tube. The vanes are configured to agitate the particles during rotation of the reactor tube.

Another aspect of the disclosure is the reactor tube assembly described above, wherein the drive motor is movable so that the reactor tube is translatable along its central axis.

Another aspect of the disclosure is the reactor tube assembly described above, wherein the reactor tube assembly further includes a plasma-generating device operably arranged adjacent or at least partially within the input section of the reactor tube. The plasma-generating device has active and inactive operational states. No active portion of the plasma-generating device resides adjacent the outer surface of the reactor tube.

Another aspect of the disclosure is the reactor tube assembly described above, wherein the plasma-generating device is configured to receive a precursor gas and i) generate therefrom a plasma when the plasma-generating device is in the active state, and ii) to pass the precursor gas without forming a plasma when the plasma-generating device is in the inactive state.

An aspect of the disclosure is a plasma-enhanced atomic layer deposition (PE-ALD) system. The system includes the reactor tube assembly described above. The system also includes a chamber having top and bottom sections that define a chamber interior. The chamber is configured such that the top and bottom sections have an open position that provides access to the chamber interior and a closed position wherein the chamber interior holds a vacuum. The reactor tube assembly is operably arranged relative to the chamber so that the reactor tube resides within the chamber interior. At least one of the plasma-generating device and reactor tube is axially movable so that the plasma-generating device and the reactor tube can be operably disposed relative to one another when the chamber is in the closed position.

Another aspect of the disclosure is the system described above, wherein at least a portion of the plasma-generating device resides within the interior of the reactor tube at the input section when the plasma-generating device and the reactor tube are operably disposed relative to one another.

An aspect of the disclosure is a method of processing particles using plasma-enhanced atomic layer deposition (PE-ALD). The method includes a) providing the particles to an interior of a reactor tube that has a central axis, proximal and distal open ends, a body made of a dielectric material and having an outer surface that defines the interior, an input section that includes the proximal open end, an output section that includes a distal open end closed by a support plate, a center section between the input and output sections and sized to contain the particles and that is wider than the input and output sections, with at least one aperture formed in the outer surface at the output section. The method also includes b) forming a vacuum within the interior of the reactor tube. The method also includes c) rotating the reactor tube. The method also includes generating a first plasma from a first precursor gas using a plasma-generating device operably disposed immediately adjacent or at least partially within the input section of the reactor tube. No active portion of the plasma-generating device resides adjacent the outer surface. The method also includes e) flowing the first plasma through the interior of the reactor tube from the input section to the output section, with the first plasma causing a first chemical reaction on each of the particles. The first plasma exits the interior of the reactor tube through the at least one aperture in the output section.

Another aspect of the disclosure is the method described above, wherein the input and output sections have a first diameter and the center section has a second diameter in the range (1.25)·D1≦D2≦(3)·D1.

Another aspect of the disclosure is the method described above, wherein the method further includes f) purging the interior of the reactor tube. The method also includes g) flowing a second precursor gas through the plasma-generating device, including either: i) not activating the plasma-generating device so that the second precursor gas flows into the interior of the reactor tube and causes a second chemical reaction on the particles to form coating, or ii) activating the plasma-generating device so that a second plasma is formed from the second precursor gas and flows into the interior of the reactor tube and causes a third chemical reaction.

Another aspect of the disclosure is the method described above, wherein the method further includes sequentially repeating acts d) through g) to create a PE-ALD film.

Another aspect of the disclosure is the method described above, wherein the method further includes alternately forming first and second coatings to define a PE-ALD film on each of the particles. The PE-ALD film consists of multiple layers of the second coating.

Another aspect of the disclosure is the method described above, wherein the method further includes f) purging the interior of the reactor tube. The method further includes g) providing the second precursor gas to the interior of the reactor tube without flowing the second precursor gas through the plasma-generating device. The second precursor gas flows into the interior of the reactor tube and causes a second chemical reaction on the particles to form coating.

An aspect of the disclosure is a method of processing particles using plasma-enhanced atomic layer deposition (PE-ALD). The method includes a) providing the particles to an interior of a reactor tube that has a central axis, proximal and distal open ends, a body made of a dielectric material and having an outer surface that defines the interior, an input section that includes the proximal open end, an output section that includes the distal open end which is closed by a support plate, a center section between the input and output sections and sized to contain the particles and that is wider than the input and output sections, with at least one aperture formed in the outer surface at the output section. The method also includes b) forming a vacuum within the interior of the reactor tube. The method also includes c) rotating the reactor tube. The method also includes d) operably arranging a plasma-generating device immediately adjacent or at least partially within the input section of the reactor tube. No active portion of the plasma-generating device resides adjacent the outer surface. The plasma-generating device has an active state that generates a plasma from a first precursor gas and an inactive state that allows for a first precursor gas to flow through the plasma-generating device without being converted to a plasma. The method also includes e) flowing the first precursor gas through the plasma-generating device in the inactive state and into the interior of the reactor tube from the input section to the output section, with the first precursor gas causing a first chemical reaction on each of the particles and forming a first coating therein. The first precursor gas exits the interior of the reactor tube through the at least one aperture in the output section. The method also includes f) purging the first precursor gas from the interior of the reactor tube. The method also includes g) flowing a second precursor gas through the plasma-generating device while in the active state to form a plasma. The plasma chemically reacts with the first coating on the particles to form a second coating. The first plasma exits the interior of the reactor tube through the at least one aperture in the output section.

Another aspect of the disclosure is the method described above, wherein the plasma includes oxygen radicals.

Another aspect of the disclosure is the method described above, wherein the plasma includes nitrogen radicals.

Another aspect of the disclosure is the method described above, wherein the plasma-generating device includes either a hollow-cathode plasma source or a hollow-anode plasma source.

Additional features and advantages are set forth in the Detailed Description that follows, and in part will be readily apparent to those skilled in the art from the description or recognized by practicing the embodiments as described in the written description and claims hereof, as well as the appended drawings. It is to be understood that both the foregoing general description and the following Detailed Description are merely exemplary, and are intended to provide an overview or framework to understand the nature and character of the claims.

### BRIEF DESCRIPTION OF THE DRAWINGS

The accompanying drawings are included to provide a further understanding, and are incorporated in and constitute a part of this specification. The drawings illustrate one or more embodiment(s), and together with the Detailed Description serve to explain principles and operation of the various embodiments. As such, the disclosure will become more fully understood from the following Detailed Description, taken in conjunction with the accompanying Figures, in which:

FIG. 1A is a top elevated view of an example PE-ALD system according to the disclosure, wherein the chamber is shown in the closed position;

FIG. 1B is a front view of the PE-ALD system wherein the chamber is in the open position;

FIG. 1C is similar to FIG. 1B except that there is an extra gas pipe connecting the flow controller to the chamber interior that bypasses the plasma-generating device;

FIG. 2A is a close-up side view of an example reactor tube assembly of the PE-ALD system disclosed herein;

FIG. 2B is an end-on view of an example reactor tube of the reactor tube assembly of FIG. 2A; and

FIGS. 3A through 3D are side views similar to that of FIG. 2A and that illustrate various process steps for using the PE-ALD system to perform PE-ALD coating of particles.

### DETAILED DESCRIPTION

Reference is now made in detail to various embodiments of the disclosure, examples of which are illustrated in the accompanying drawings. Whenever possible, the same or like reference numbers and symbols are used throughout the drawings to refer to the same or like parts. The drawings are not necessarily to scale, and one skilled in the art will recognize where the drawings have been simplified to illustrate the key aspects of the disclosure.

The claims as set forth below are incorporated into and constitute part of this detailed description.

Cartesian coordinates are shown in some of the Figures for the sake of reference and are not intended to be limiting as to direction or orientation.

The term “particles” as used herein includes small objects (e.g., powders, microspheres, granules, etc.) generally less than 1 mm in size, and typically less than 0.5 mm in size. The surfaces of the particles can be smooth, undulating, porous, etc. While particles can be spherical, rounded, oblate, etc., their shape is not so limited and can be any reasonable shape amenable for ALD-based processing.

The acronym RPM used herein stands for “revolutions per minute.”

PE-ALD System

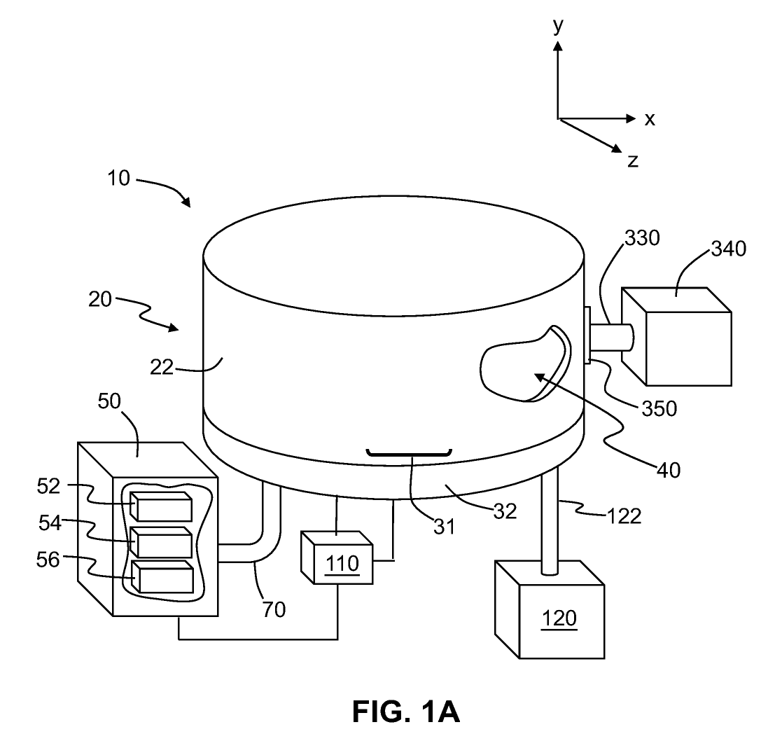

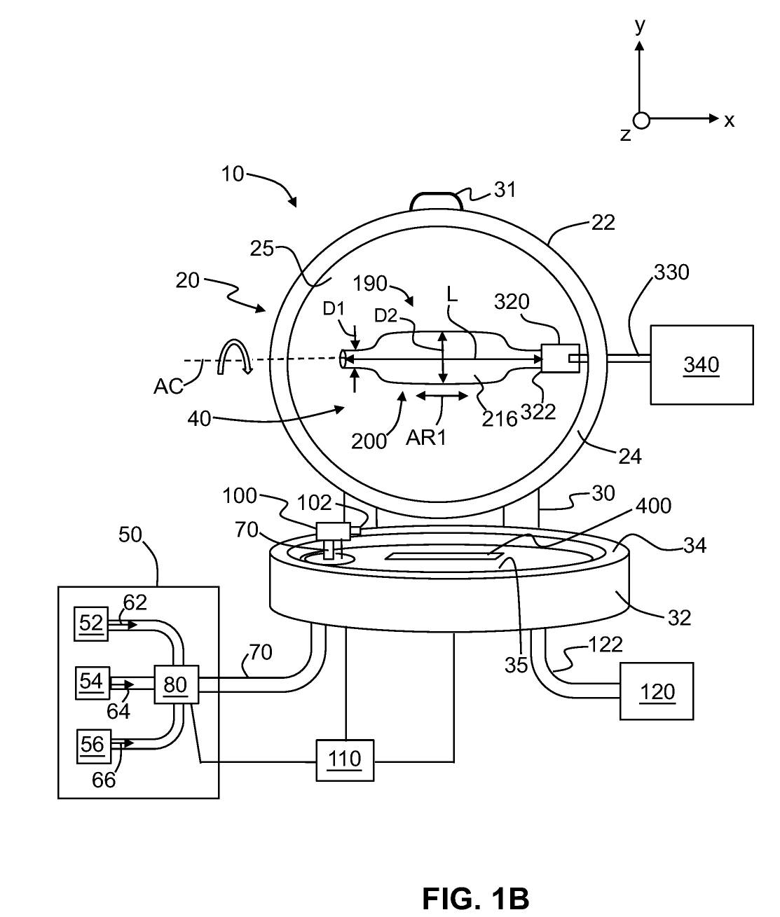

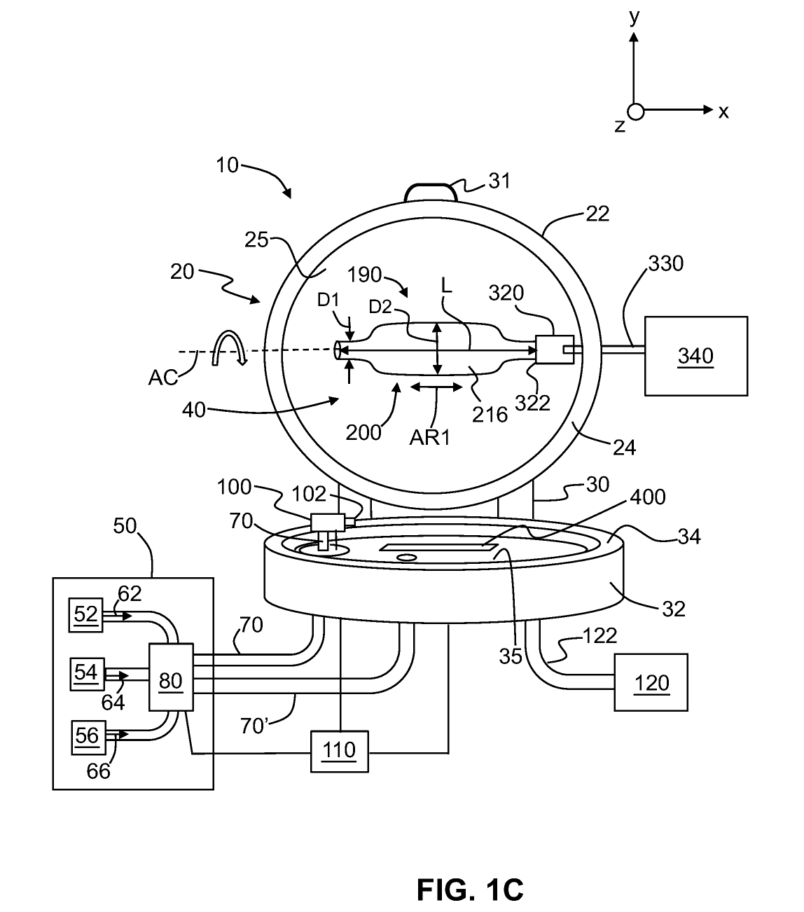

FIG. 1A is a top elevated view of an example PE-ALD system (“system”) 10 as disclosed herein. FIG. 1B shows a front-on view of the system 10 in the open position, as explained below. The system 10 includes a chamber 20 defined by a top section 22 and a bottom section 32. In an example, the top and bottom sections 22 and 32 of chamber 20 are cylindrical and include respective edges 24 and 34 that interface to form a chamber interior 40 that can be vacuum sealed. The top and bottom sections 22 and 32 are operably connected by a hinge 30 that allows for the top section 22 to swung open from the bottom section 32 (e.g., manually, using a handle 31), thereby allowing access to the chamber interior 40, as shown in FIG. 1B. The top section 22 has a ceiling 25 and the bottom section 32 has a floor 35. In an example, the chamber interior 40 has a cylindrical shape with a circular cross-section having a diameter in the range from 250 mm to 500 mm.

The system 10 includes a gas supply system 50 having at least first and second precursor gas sources 52 and 54 that respectively contain first and second precursor gases 62 and 64. The gas supply system 50 also includes a purge gas source 56 that contains a purge gas 66, such as an inert gas (e.g., N, Ar, He, etc.). The first and second precursor gas sources 52 and 54 are operably connected to a gas pipe 70 via a flow controller 80 that controls the flow of the first and second precursor gases 62 and 64 and the purge gas 66 into the gas pipe 70. The gas pipe 70 is operably connected to a plasma-generating device 100 operably arranged downstream of the flow controller 80. In an example, the flow controller 80 can be operated such that at least one of the first and second precursor gases 62 and 64 can be mixed with an inert gas (e.g., purge gas 66), such as Nitrogen or Argon.

The plasma-generating device 100 includes an output section 102, which in an example is in the form of or otherwise includes a nozzle.

In one example, the plasma-generating device 100 includes a hollow cathode plasma source. In another example, the plasma-generating device 100 includes a hollow anode plasma source, an example of which is described in U.S. Pat. No. 3,515,932. In an example, the hollow cathode and hollow anode plasma-generating devices 100 can operate at frequency in the range from 2 KHz to 13.56 MHz.

In another example, the plasma-generating device 100 includes an electron-cyclotron resonance (ECR) plasma source. In an example, the ECR plasma source has a microwave source coupled with a magnetic field provided by external coils. The frequency in the magnetic coil drive and the magnetic field strength are designed to match the microwave frequency. For example, if the microwave frequency is 2.4 Ghz, the magnetic field of 875 Gauss produces an electronic cyclotron frequency of 2.4 Ghz and the rotational movement of the electrons is in resonance with the microwave. This increases the probably of collisions between the electrons and the neutral gases, creating ionized gasses (plasmas).

Generally speaking, the plasma-generating device 100 is designed to be relatively compact. In an example, the plasma-generating device 100 has a generally cylindrical shape with an axial length between 50 and 100 mm and a diameter between 20 mm and 50 mm.

The plasma-generating device 100 and the flow controller 80 are operably connected to a controller 110, which is configured to control the operation of the plasma-generating device 100 and the flow controller 80. In an example, the controller 110 includes instructions embodiment in a non-transitory computer-readable medium (e.g., software and/or firmware) that causes the plasma-generating device 100 to generate a plasma and causes the flow controller 80 to control the flow of precursor gases 62 and 64, and purge gas 66. In an example, the controller 110 also provides power to plasma-generating device 100.

In an example, the plasma-generating device 100 includes two operational states: an active state in which gas passing therethrough is converted to a plasma and an inactive state in which gas passing therethrough is not converted to a plasma, i.e., it passes through unaltered. The controller 110 can be used to define the operational state of the plasma-generating device 100.

The system 10 also includes a vacuum system 120 operably connected to the chamber interior 40 via a vacuum line 122. The vacuum system 120 is used to pull a vacuum in the chamber interior 40 when the system 10 is in the closed position, i.e., the top and bottom sections 22 and 32 of chamber 20 are interfaced at respective the edges 24 and 34, as shown in FIG. 1A.

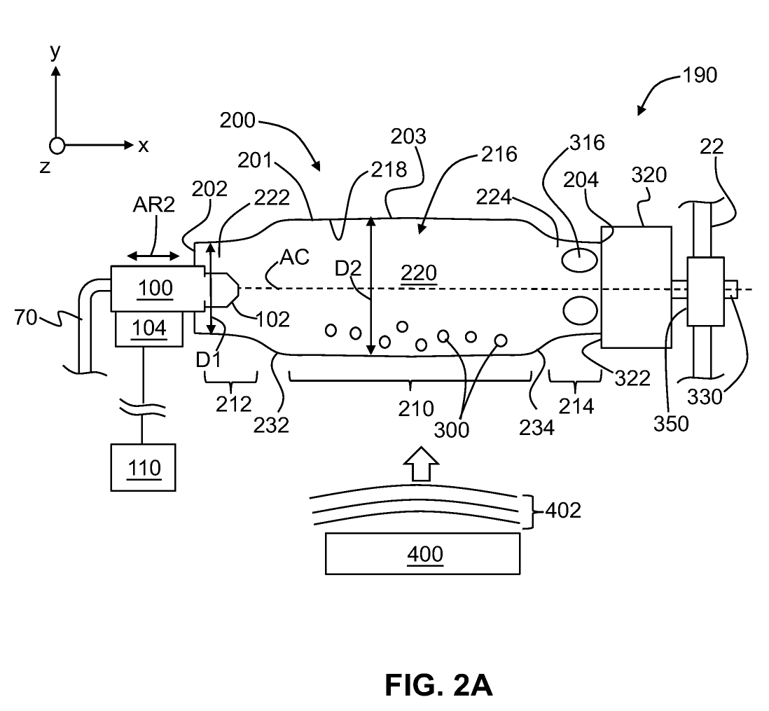

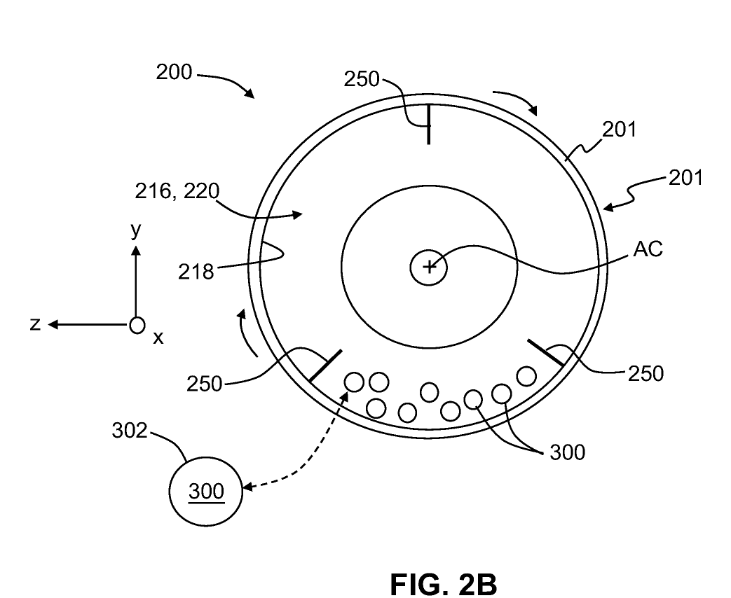

FIG. 2A is a side view an example reactor tube assembly 190 that forms part of the system 10. The reactor tube assembly 190 includes a reactor tube 200 having a central axis AC, a body 201 having an outer surface 203 and proximal and distal open ends 202 and 204. FIG. 2B is an end-on view of the reactor tube 200. An exemplary reactor tube 200 includes a wide central section 210 surrounded on each side by narrow-end sections 212 and 214 that respectively include proximal and distal open ends 202 and 204. The narrow-end section 212 is also referred to herein as an “input section” while the narrow-end section 214 is referred to as an “output section” for reasons that are discussed below.

In an example, the wide central section 210 and narrow-end sections 212 and 214 are cylindrical, e.g., having a substantially circular cross-sectional shape. The reactor tube 200 is made of a material that does not readily react to a plasma or reactive gases. Example materials include dielectric materials such as quartz and any one of a number of different types of ceramics.

The reactor tube 200 includes an interior 216 with an inner surface 218 defined by a body 201. The interior 216 has a wide central interior portion 220 associated with wide central section 210 and two narrow interior portions 222 and 224 respectively defined by the narrow-end sections 212 and 214. In an example, respective curved transition regions 232 and 234 join the wide central section 210 to the narrow-end sections 212 and 214.

In an example illustrated in FIGS. 1B and 2A, the narrow-end sections 212 and 214 have the same diameter D1 and the wide central section 210 has a diameter D2, wherein (1.25)·D1≦D2≦(3)·D1 In an example, the reactor tube 200 has an axial length L in the range from 125 mm to 225 mm. In an example, the diameter D1 is in the range from 10 mm to 20 mm and the diameter D2 is in the range from 20 mm to 60 mm, wherein D2>D1. As discussed further below, the reactor tube 200 can be rotated about its central axis AC and so can be referred to herein as a “rotary reactor tube.”

It is noted that plasma-generating device 100 is relatively compact and is operably disposed relative to the proximal open end 202 of reactor tube 200, and in particular is arranged immediately adjacent thereto to or at least partially within the interior portion 222 of input section 212 of the reactor tube 200. This configuration avoids the use of active plasma-generating elements or devices, such as RF coils, electrodes, etc., around the outer surface 203 of reactor tube 200. An example of an inactive component of the plasma-generating device 100 is its housing or a mounting feature or like structural elements (not shown). Thus, in an example, the plasma-generating device 100 has no active portion that resides adjacent to the outer surface 203 of reactor tube 200.

FIG. 2A shows particles 300 residing in the interior portion 220 of wide central section 210. FIG. 2B includes a close-up view of an example particle 300, which has an outer surface 302. Example types of particles 300 suitable for coating are discussed below, and generally include any material that is amenable to a conventional ALD process, i.e., wherein a precursor gas 62 and 64 can be used to react with (including adhering to) the outer surface 302 of particles 300. In an example, the size of the particles 300 is in the range from 0.01 micron to 100's of micron. In an example, the outer surface 302 of particles 300 can be defined by a coating (e.g., an oxide coating) that is a different material than the body or bulk of the particle 300.

In an example best seen in FIG. 2B, the wide central section 210 of reactor tube 200 optionally includes vanes 250 that extend radially inward from the inner surface 218 toward the central axis AC and that assist in keeping particles 300 agitated within the interior portion 220 to ensure an even coating of outer surfaces 302 of particles 300 with minimal agglomeration.

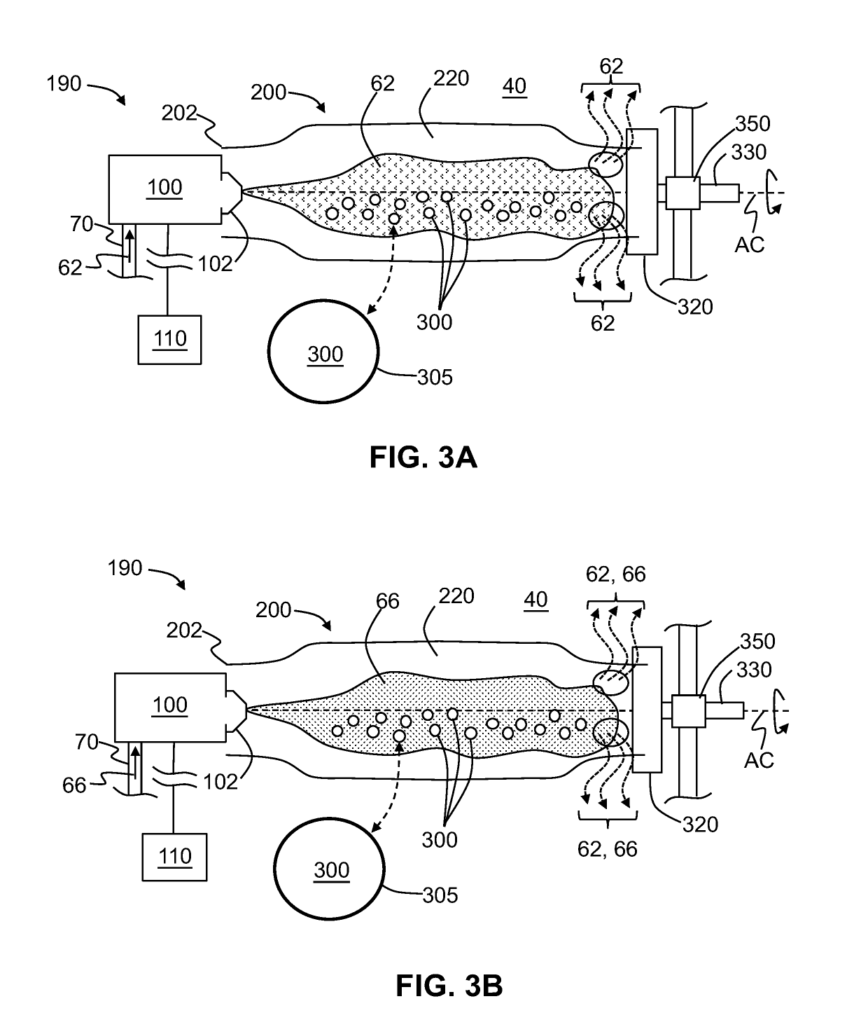

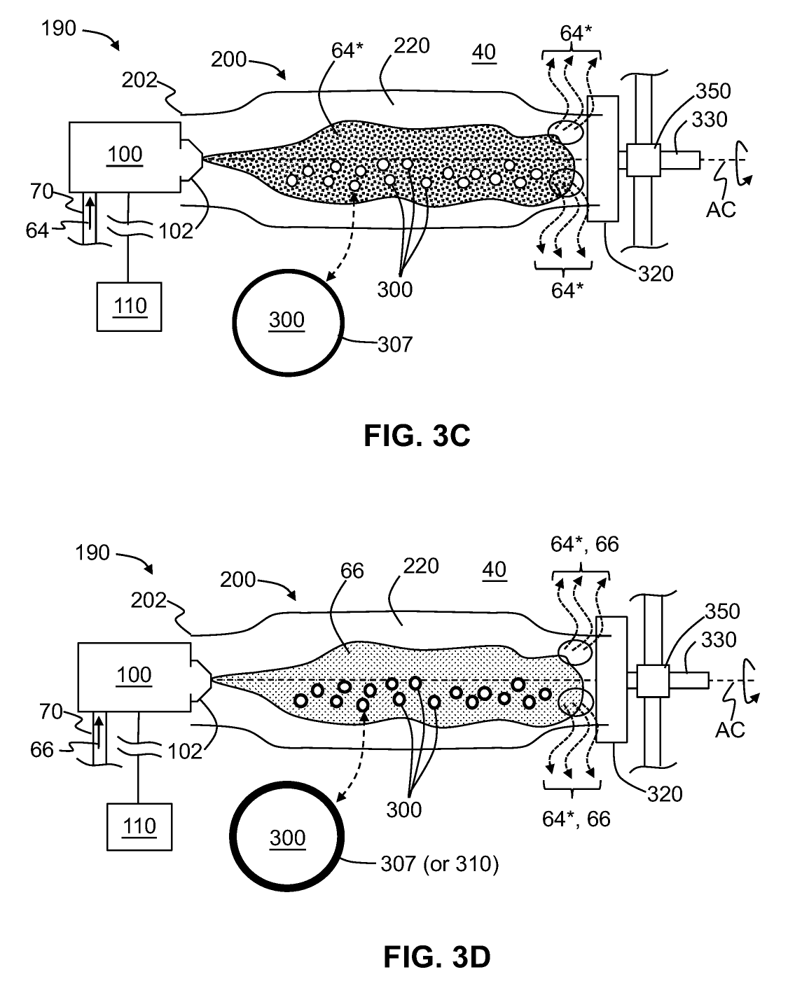

With reference again to FIG. 2A, in an example, the reactor tube 200 includes one or more apertures 316 formed in the narrow-end section 214. The one or more apertures 316 are configured to allow for the flow of gas (including plasma, as discussed below) out of the interior portion 224 of narrow-end section 214, thereby making the narrow-end section 214 an output section 102 as discussed above. This is because the reactor tube assembly 190 includes a support member 320 with a front surface 322 that at least substantially closes off the otherwise distal open end 204 of reactor tube 200. In an example, the support member 320 is in the form of an end plate. In an example, a portion of the narrow-end section 214 extends into the support member 320, as shown in the cross-sectional views of FIGS. 3A-3D, introduced and discussed below, to assist in securing the reactor tube 200 to the support member 320.

The reactor tube assembly 190 also includes a drive shaft 330 and a drive motor 340. The drive shaft 330 mechanically connects the support member 320 to the drive motor 340. The drive motor 340 preferably resides outside of the chamber 20. In an example, the drive shaft 330 passes through a sealed bearing or like rotary feed through 350 in the chamber 20, e.g., in the top section 22. The drive motor 340 serves to rotate the drive shaft 330 (i.e., the drive motor 340 rotatably drives the drive shaft 330), which in turn drives the rotation of reactor tube 200 and support member 320 attached thereto about the central axis AC. In an example, the reactor tube assembly 190 is configured to axially rotate the reactor tube 200 at a rotation rate RR in the range from 0 RPM to 300 RPM. In an example, the rotation rate RR is at least 1 RPM.

In an example, the reactor tube assembly 190 is configured so that the reactor tube 200 can be axially translated, i.e., can be moved back and forth in the x-direction, as indicated by arrow AR1. This axial movement can be accomplished, for example, by axially moving the drive motor 340. The axial movement of reactor tube 200 allows for the plasma-generating device 100 to be operably arranged relative to the proximal open end 202 of input section 212. In an example, at least a portion of the plasma-generating device 100 (e.g., output section 102) resides within the interior portion 222 of input section 212 of reactor tube 200 as shown in FIG. 2A.

The positioning of plasma-generating device 100 can be accomplished in one example by moving the reactor tube 200 in the +x direction while the system 10 is in the open position so that there is adequate clearance between the plasma-generating device 100 and the proximal open end 202 of reactor tube 200 to place the chamber 20 is in the closed position. While the chamber 20 is in the open position and the proximal open end 202 accessible to a user, the particles 300 to be coated can be added to the interior 216 of reactor tube 200.

In another example, the plasma-generating device 100 can be positioned by moving the plasma-generating device 100. In an example, this is accomplished by mounting or otherwise supporting the plasma-generating device 100 on a translation device 104 (e.g., a translation stage), which is configured to translate the plasma-generating device 100 at least in the x-direction, as indicated by arrow AR2. In an example, the translation device 104 is operably connected to the controller 110, which is configured to control the movement (translation) of plasma-generating device 100. This configuration allows for the plasma-generating device 100 to be backed out of the interior portion 222 of narrow-end section 212 of reactor tube 200 so that the chamber 20 can be moved to the open position and then inserted into the interior portion 222 when the chamber 20 is in the closed position.

The system 10 also includes at least one heating device 400 operably arranged to radiate heat (i.e., infrared energy) 402 when activated. In an example, the heating device 400 is arranged within the chamber 20, e.g., on the floor 35 of bottom section 32 so that the heating device 400 is in close proximity to the reactor tube 200 when the chamber 20 is in the closed position. The at least one heating device 400 can also be arranged on the ceiling 25 of top section 22 of chamber 20. In an example, multiple heating devices 400 are employed. The at least one heating device 400 is electrically connected to the controller 110 or can be connected to an independent power source (not shown).

Methods of Particle Coating Using the PE-ALD System

Once the particles 300 are placed into the interior 216 of reactor tube 200, the top section 22 of chamber 20 is then closed to form sealed chamber interior 40. At this point, the reactor tube 200 is moved in the −x direction (or plasma-generating device 100 is moved in the +x direction) so that a portion of the plasma-generating device 100 (e.g. output section 102) resides in its operable position, which in examples is either immediately adjacent or within the interior portion 222 of input section 212 of the reactor tube 200, as shown in FIG. 2A.

At this point, the vacuum system 120 is used to reduce the pressure in the chamber interior 40, e.g., in the range from 50 millitorr to 500 Torr. Because the reactor tube 200 is open at the proximal open end 202 and also at the apertures 316, the pressure in the interior 216 of reactor tube 200 is initially the same as that of the chamber 20.

The drive motor 340 is then activated, thereby initiating the rotation of reactor tube 200 about the central axis AC. As discussed above, in an example, the vanes 250 in the interior portion 220 of wide central section 210 serve to agitate the particles 300 so that do not rest on the inner surface 218 of reactor tube 200 and spend most of their time agitated within the interior portion 220. In addition, the heating device 400 is activated to generate heat 402, which serves to heat the particles 300, e.g., to a temperature in the range from 100° C. to 400° C., to facilitate a chemical reaction. In an alternative embodiment, the entire chamber 20 is heated via the heating device 400 so that the heated chamber 20 generates black-body heat radiation 402 that is incident upon and that heats the particles 300.

FIGS. 3A through 3D illustrate an example process of forming an ALD coating or film on the particles 300. With reference to FIGS. 1A, 1B and 3A, once the system 10 is configured as described above, the controller 110 activates the flow controller 80 to cause the first precursor gas 62 from the first precursor gas source 52 to flow through the gas pipe 70 to the plasma-generating device 100. In the present example, the controller 110 does not activate the plasma-generating device 100 (i.e., it sets or leaves the plasma-generating device 100 in the inactive state) so that the first precursor gas 62 flows directly through the plasma-generating device 100 without being subjected to plasma-generating forces. The first precursor gas 62 flows from the output section 102 of plasma-generating device 100 into the input section 212 of reactor tube 200 and into the interior 216, and in particular into the interior portion 220 of wide central section 210. Here, the first precursor gas 62 mixes with the particles 300 and interacts with the outer surface 302 of each particle 300 to form an initial coating 305 therein, wherein the initial coating 305 includes one or more of the constituents of the first precursor gas 62. The first precursor gas 62 can be provided as a continuous flow or as one or more pulses.

The first precursor gas 62 flows from the interior portion 220 of wide central section 210 to the interior portion 224 of the narrow-end section 214 due to the pressure differential created within the interior 216 of reactor tube 200. The (unreacted) first precursor gas 62 flows out of the interior 216 via the apertures 316 in the narrow-end section 214 and enters the chamber interior 40, where it is pumped out of the chamber interior 40 by the vacuum system 120.

With reference to FIG. 3B, once the initial coating 305 is formed, the controller 110 then causes the flow controller 80 to stop the flow of first precursor gas 62 and initiates the flow of purge gas 66 from the purge gas source 56. The controller 110 leaves the plasma-generating device 100 in the inactive state so that the purge gas 66 flows through the plasma-generating device 100 and into the interior 216 of reactor tube 200 without being subjected to plasma-generating forces. The purge gas 66 and any remaining first precursor gas 62 flows out of the apertures 316 until substantially only purge gas 66 remains in the interior 216 of reactor tube 200.

With reference to FIG. 3C, once the purge step is completed, the controller 110 then causes the flow controller 80 to stop the flow of the purge gas 66 and initiates the flow of second precursor gas 64 from the second precursor gas source 54. The controller 110 also activates the plasma-generating device 100 so that as the second precursor gas 64 flows through the plasma-generating device 100 it is converted to a plasma gas (“plasma”) 64*. The plasma gas 64* can include ions, such as radicalized molecules of the second precursor gas 64 (e.g., oxygen radicals O*, N*, etc.). The plasma 64* flows out of the output section 102 of plasma-generating device 100 and into the interior 216 of reactor tube 200. The plasma 64* travels through the interior portion 220 of wide central section 210 and reacts with the initial coating 305 to form a second coating 307. The second coating 307 includes one or more of the constituents of plasma 64*. The (unreacted) plasma 64* flows out of the apertures 316 at the narrow-end section 214 and into the chamber interior 40, where it is pumped out of the chamber interior 40 via the vacuum system 120.

Once the second coating 307 is formed, the controller 110, then causes the flow controller 80 to stop the flow of second precursor gas 64 and initiates the flow of purge gas 66 from the purge gas source 56 to perform another purge of the reactor tube 200. Again, the plasma-generating device 100 is set to the inactive state during the purge step so that the purge gas 66 flows through the plasma-generating device 100 and into the interior 216 of reactor tube 200 without being subjected to plasma-generating forces. The purge gas 66 and any remaining plasma 64* (as well as any unconverted second precursor gas 64 and volatile byproducts) flows out of the apertures 316 until substantially only the purge gas 66 remains in the interior 216 of reactor tube 200.

The above process steps or acts can be repeated until a final film 310 is formed made up of multiple layers of the second coatings 307.

One potential by-product of forming a plasma 64* from the second precursor gas 64 is the unintentional buildup of an ALD film inside the plasma-generating device 100. In the formation of certain types of films 310, the ALD film buildup inside the plasma-generating device 100 may be undesirable. For example, when forming film 310 involves depositing a metal, a sufficiently thick metal film might form in the plasma-generating unit 100 and cause the plasma-generating unit 100 (e.g., electrodes therein to “short out” and cease to operate. This is less likely to happen when the formation of film 310 involves only non-conducting materials. In the case where the ALD film buildup inside the plasma-generating device 100 is detrimental to its operation, several options are available.

A first option is to clean the inner surfaces 218 of the plasma-generating device 100 on which the ALD film is formed (e.g., electrode surfaces) by initiating the formation of a different (“clean up”) plasma 64* within the plasma-generating device 100. This can be done between deposition cycles. For example, after the desired coating is deposited onto the particles 300, and the particles 300 are removed, the system 10 can be closed and operated with a different gas designed to etch the recently deposited ALD material from the inner surfaces 218 of the plasma-generating device 100. For example, in the case of where the ALD film formed in the plasma-generating device 100 is an oxide, a chlorine-based or fluorine-based plasma can be generated to etch away the ALD deposited oxide material.

A second option is available when only one of the two precursor gases 62 and 64 needs to be excited into or “converted” into to a plasma. In this case, the first precursor gas 62 or second precursor gas 64 that needs to be converted to a plasma can be the only precursor gas 62 or 64 that runs through the plasma-generating device 100, whereas the other non-plasma precursor gas can be introduced into the chamber interior 40 via a separate gas line 70′, as shown in FIG. 1C. This other non-plasma precursor gas makes its way into the interior 216 of rotary reactor tube 200 via the proximal open end 202 and the apertures 316 at the distal open end 204 and interacts with the particles 300 that reside in the interior portion 220.

A third option is simply the periodic replacement of the plasma-generating device 100 once any ALD film buildup starts adversely affecting the performance of the plasma-generating device 100.

Once the final film 310 is formed on the particles 300, the chamber 20 can be opened and the coated particles 300 removed from the reactor tube 200.

In various examples, one or both precursor gases 62 and 64 can be made into a corresponding plasma. For example, a variation of the above-described method includes forming plasma from the first precursor gas 62 by activating the plasma-generating device 100 as the first precursor gas 62 passes therethrough while allowing the second precursor gas 64 to pass into the interior 216 of reactor tube 200 in its original state to form the second coatings 307. Another example has the plasma-generating device 100 in the active state for both the first and second precursor gases 62 and 64 to form respective plasmas during their flow sequence.

### EXAMPLES

The following sets forth four different examples of the particles 300, the first and second precursor gases 62 and 64, and the resulting final film 310

### Example 1

The particles 300=Lithium cobalt oxide (LiCoO₂); the first precursor gas 62 is TMA (trimethylaluminum); the second precursor gas 64 is O₂, which is converted to O* by the plasma-generating device 100; and the final film 310 is alumina.

### Example 2

The particles 300=silicon; the first precursor gas 62 is TDMAT (tetrakis(dimethylamido)titanium(IV)); the second precursor gas 64 is N₂, which is converted to N* by the plasma-generating device 100; and the final film 310 is TiN.

### Example 3

The particles 300=Tungsten carbide; the first precursor gas 62 is Bis(ethylcyclopentadienal)platinum(II); the second precursor gas 64 is O₂, which is converted to O* by the plasma-generating device 100; and the final film 310 is platinum.

### Example 4

The particles 300=Barium Oxide (BaO). The first precursor gas 62 is TDMAT (tetrakis(dimethylamido)titanium(IV)); the second precursor gas 64 is O₂, which is converted to O* by the plasma-generating device 100; and the final film 310 is TiO₂.

Other example materials for the particles 300 include glass, ceramic, oxide-based particles, plastics, polymers, etc., can be used, and other precursor gases can also be used beyond those described in the four Examples.

It will be apparent to those skilled in the art that various modifications to the preferred embodiments of the disclosure as described herein can be made without departing from the spirit or scope of the disclosure as defined in the appended claims. Thus, the disclosure covers the modifications and variations provided they come within the scope of the appended claims and the equivalents thereto.

What is claimed is:

1. A system for performing plasma-enhance atomic layer deposition (PE-ALD) of particles using at least first and second precursor gases, comprising:
a chamber having top and bottom sections that define a chamber interior, the chamber configured such that the top and bottom sections have an open position that provides access to the chamber interior and a closed position wherein the chamber interior holds a vacuum;
a reactor tube assembly operably arranged relative to the chamber, the reactor tube assembly including a reactor tube that resides within the chamber interior and having a central axis, an outer surface, an interior, an input section, a center section that contains the particles, and an output section that includes at least one aperture in the outer surface, the reactor tube assembly being configured to rotate the reactor tube about the central axis;
a gas supply system that includes at least first and second precursor gases;
a plasma-generating device arranged within the chamber interior and adjacent or at least partially within the input section of the reactor tube along the central axis of reactor tube, the plasma-generating device having active and inactive states of operation and being operably connected to the gas supply system and configured to receive at least one of the first and second precursor gases, and when in the active state form therefrom at least one corresponding plasma that is outputted therefrom and into the interior of the reactor tube via the input section; and
a vacuum system that forms the vacuum in the chamber interior in the closed position, thereby forming the vacuum in the interior of reactor tube that causes the plasma to flow through the interior of the reactor tube and react with the particles therein.

2. The system according to claim 1, wherein at least one of the plasma-generating device and the reactor tube is axially movable along the central axis so that the plasma-generating device can be operably positioned relative to the input section of the reactor tube.

3. The system according to claim 1, wherein the top and bottom sections are mechanically coupled by a hinge.

4. The system according to claim 1, wherein the reactor tube is made of quartz or a ceramic.

5. The system according to claim 2, wherein the plasma-generating device is operably supported by a translation device configured to translate the plasma-generating device at least along the central axis of the reactor tube.

6. The system according to claim 1, wherein the reactor tube assembly further includes:
a drive motor that resides external to the chamber interior;
a support plate that supports the reactor tube at the output section, and;
a drive shaft that mechanically connects the support plate to the drive motor.

7. The system according to claim 6, wherein the drive motor is movable such that the reactor tube is translatable along the central axis.

8. The system according to claim 1, further comprising at least one heating device operably arranged to provide heat to the particles contained in the reactor tube.

9. The system according to claim 1, wherein the plasma-generating device includes either a hallow-anode plasma source or a hollow-cathode plasma source.

10. The system according to claim 9, wherein the drive frequency for the plasma source is between 200 kHz and 15 MHz.

11. The system according to claim 1, wherein the plasma-generating device includes an electron-cyclotron resonance (ECR) plasma source.

12. The system according to claim 11 wherein the ECR plasma source has a drive frequency of 2.4 GHz.

13. The system according to claim 1, wherein the plasma-generating device has a substantially cylindrical shape with an axial length between about 50 and 100 mm and a diameter between about 20 mm to 50 mm.

14. The system according to claim 1, wherein the reactor tube has the input and output sections have a first diameter D1, the center section has a second diameter D2, and wherein (1.25)·D1≦D2≦(3)·D1.

15. A reactor tube assembly for a plasma-enhanced atomic layer deposition (PE-ALD) system for coating particles, comprising:
a reactor tube having a central axis, proximal and distal open ends, a body made of a dielectric material and having an outer surface that defines an interior, an input section that includes the proximal open end, an output section that includes that distal open end, a center section between the input and output sections and sized to contain the particles, with at least one aperture formed in the outer surface at the output section;
a support plate operably attached to the distal open end of the reactor tube;
a drive motor; and
a drive shaft that mechanically connects the drive motor to the support plate so that the reactor tube rotates about its central axis when the drive motor rotatably drives the drive shaft.

16. The reactor tube assembly according to claim 15, wherein the input and output sections have a first diameter D1, the center section has a second diameter D2, and wherein (1.25)·D1≦D2≦(3)·D1.

17. The reactor tube assembly according to claim 15, further comprising inwardly extending vanes in the center section of the reactor tube, wherein the vanes are configured to agitate the particles during rotation of the reactor tube.

18. The reactor tube assembly according to claim 15, wherein the drive motor is movable so that the reactor tube is translatable along its central axis.

19. The reactor tube assembly according to claim 15, further comprising:
a plasma-generating device operably arranged adjacent or at least partially within the input section of the reactor tube, wherein the plasma-generating device has active and inactive operational states and wherein no active portion of the plasma-generating device resides adjacent the outer surface of the reactor tube.

20. The reactor tube assembly according to claim 19, wherein the plasma-generating device is configured to receive a precursor gas and i) generate therefrom a plasma when the plasma-generating device is in the active state, and ii) to pass the precursor gas without forming a plasma when the plasma-generating device is in the inactive state.

21. A plasma-enhanced atomic layer deposition (PE-ALD) system, comprising:
the reactor tube assembly according to claim 19; and
a chamber having top and bottom sections that define a chamber interior, the chamber configured such that the top and bottom sections have an open position that provides access to the chamber interior and a closed position wherein the chamber interior holds a vacuum; and
wherein the reactor tube assembly is operably arranged relative to the chamber so that the reactor tube resides within the chamber interior and wherein at least one of the plasma-generating device and reactor tube is axially movable so that the plasma-generating device and the reactor tube can be operably disposed relative to one another when the chamber is in the closed position.

22. The plasma-enhanced atomic layer deposition system according to claim 21, wherein at least a portion of the plasma-generating device resides within the interior of the reactor tube at the input section when the plasma-generating device and the reactor tube are operably disposed relative to one another.

23. A method of processing particles using plasma-enhanced atomic layer deposition (PE-ALD), comprising:
a) providing the particles to an interior of a reactor tube that has a central axis, proximal and distal open ends, a body made of a dielectric material and having an outer surface that defines the interior, an input section that includes the proximal open end, an output section that includes a distal open end closed by a support plate, a center section between the input and output sections and sized to contain the particles and that is wider than the input and output sections, with at least one aperture formed in the outer surface at the output section;
b) forming a vacuum within the interior of the reactor tube;
c) rotating the reactor tube;
d) generating a first plasma from a first precursor gas using a plasma-generating device operably disposed immediately adjacent or at least partially within the input section of the reactor tube, wherein no active portion of the plasma-generating device resides adjacent the outer surface; and
e) flowing the first plasma through the interior of the reactor tube from the input section to the output section, with the first plasma causing a first chemical reaction on each of the particles, wherein the first plasma exits the interior of the reactor tube through the at least one aperture in the output section.

24. The method according to claim 23, wherein the input and output sections have a first diameter and the center section has a second diameter in the range (1.25)·D1≦D2≦(3)·D1.

25. The method according to claim 24, further comprising:
f) purging the interior of the reactor tube; and
g) flowing a second precursor gas through the plasma-generating device, including either:
i) not activating the plasma-generating device so that the second precursor gas flows into the interior of the reactor tube and causes a second chemical reaction on the particles to form coating, or
ii) activating the plasma-generating device so that a second plasma is formed from the second precursor gas and flows into the interior of the reactor tube and causes a third chemical reaction.

26. The method according to claim 25, further comprising sequentially repeating acts d) through g) to create a PE-ALD film.

27. The method according to claim 25, further comprising alternately forming first and second coatings to define a PE-ALD film on each of the particles, wherein the PE-ALD film consists of multiple layers of the second coating.

28. The method according to claim 24, further comprising:
f) purging the interior of the reactor tube; and
g) providing the second precursor gas to the interior of the reactor tube without flowing the second precursor gas through the plasma-generating device, wherein the second precursor gas flows into the interior of the reactor tube and causes a second chemical reaction on the particles to form coating.

29. A method of processing particles using plasma-enhanced atomic layer deposition (PE-ALD), comprising:
a) providing the particles to an interior of a reactor tube that has a central axis, proximal and distal open ends, a body made of a dielectric material and having an outer surface that defines the interior, an input section that includes the proximal open end, an output section that includes the distal open end which is closed by a support plate, a center section between the input and output sections and sized to contain the particles and that is wider than the input and output sections, with at least one aperture formed in the outer surface at the output section;
b) forming a vacuum within the interior of the reactor tube;
c) rotating the reactor tube;
d) operably arranging a plasma-generating device immediately adjacent or at least partially within the input section of the reactor tube, wherein no active portion of the plasma-generating device resides adjacent the outer surface, wherein the plasma-generating device has an active state that generates a plasma from a first precursor gas and an inactive state that allows for a first precursor gas to flow through the plasma-generating device without being converted to a plasma;
e) flowing the first precursor gas through the plasma-generating device in the inactive state and into the interior of the reactor tube from the input section to the output section, with the first precursor gas causing a first chemical reaction on each of the particles and forming a first coating therein, wherein the first precursor gas exits the interior of the reactor tube through the at least one aperture in the output section;
f) purging the first precursor gas from the interior of the reactor tube; and
g) flowing a second precursor gas through the plasma-generating device while in the active state to form a plasma, wherein the plasma chemically reacts with the first coating on the particles to form a second coating, wherein the first plasma exits the interior of the reactor tube through the at least one aperture in the output section.

30. The method according to claim 29, wherein the plasma includes oxygen radicals.

31. The method according to claim 29, wherein the plasma includes nitrogen radicals.

32. The method according to claim 29, wherein the plasma-generating device includes either a hollow-cathode plasma source or a hollow-anode plasma source.
